(19) United States
(12) Patent Application Publication
(10) Pub. No.: US 2012/0042936 A1
(43) Pub. Date: Feb. 23, 2012

(54) SOLAR GENERATOR

(76) Inventors: Richard Feichtinger, Tubingen (DE); Rolf Maier, Siegen (DE)

(21) Appl. No.: 13/124,382

(22) PCT Filed: Oct. 16, 2009
(86) PCT No.: PCT/EP2009/007446

§ 371 Date: Jun. 17, 2011

(30) Foreign Application Priority Data
Oct. 17, 2008 (DE) 10 2008 053 605.9

(51) Int. Cl. H01M 10/46; H01L 31/02

(52) U.S. Cl. 136/252; 320/101

(57) ABSTRACT

The invention relates to a solar generator having a supporting structure, particularly a bicycle trailer, on which at least one wheel (2) is attached, having a solar module (3) and at least one electrical module (4, 5, 6, 7, 8, 9), characterized in that the solar module (3) is fastened to a box (10), particularly a plastic box, wherein at least one electrical module (4, 5, 6, 7, 8, 9) is provided, wherein the electrical module (4, 5, 6, 7, 8, 9) is covered from the sides by the box (10) and at least by the solar module (3) from above in order to protect it from rain.

### CROSS REFERENCE TO RELATED APPLICATIONS

This is a U.S. national stage of application No. PCT/EP2009/007446, filed on Oct. 16, 2009. Priority is claimed on German Application No. 10 2008 053 605.9 filed Oct. 17, 2008, the content of which is/are incorporated here by reference.

### BACKGROUND OF THE INVENTION

The invention concerns a solar generator with a supporting structure with at least one wheel, in particular a bicycle trailer. Trolleys and trailers, in particular bicycle trailers, are known in various embodiments.

In remote areas, where there is no electric grid available, local power generators are used to generate electricity. In most cases this is provided by power generators using gasoline or diesel fuel, with the disadvantage of the regular need to buy fuel and transport it to the generator. Thus in many areas there is no electricity available, lighting is, if at all, provided by kerosene lamps. Therefore refrigerators for cooling of drugs and other equipment dependent on electricity are missing. Generating electricity from renewable energy sources has the advantage that there is no cost for fuel and therefore no running costs. While wind and water power are strongly locally bound, solar power has the potential, next to many existing plants on roofs or on special earth mounted supports, to be designed in an easy portable way.

FR 2 795 569 A1 discloses a portable solar generator as a closed box, in which the rechargeable battery to store the energy and the charge controller as well as the inverter are housed. The box is covered by the solar panel and designed in such a way, that, depending on the position of the box on one of its sides, the solar panel is oriented to the earth's surface in one of three distinct angles, allowing to expose the solar generator in the best of its three possibilities depending on declination and time of the year and the day. The complete box weighs approximately 20 kg and can be carried by hand over short distances or loaded on a vehicle, but it cannot be carried over longer distances without support. Because of the low maximal weight the electric power data are limited, in particular due to the weight of the batteries. Furthermore there are no provisions described to prohibit heat accumulation below the covering solar panel within the box. The life expectancy of the batteries is therefore very low.

U.S. Pat. No. 6,396,239 B1 discloses a portable solar generator, in which solar panels are mounted on a pole, turnable in two axes, and can therefore be adjusted to the sun. The pole is fixed on a footing box, which contains the rechargeable battery, and on the bottom side of which footing box five rollers are fixed. The solar generator can be shifted and moved around on flat and even surfaces but only with difficulty on uneven surfaces. Furthermore, because of its high construction it is strongly prone to wind. The described plant cannot be transported easily, because it takes a lot of space in a vehicle and it can only be pulled on fairly even surface.

DE 200 13 064 U1 discloses a mobile solar power plant built on a sack barrow, which can be moved by hand over not too long distances. The electric components of the plant are mounted openly and therefore exposed to weathering conditions, in particular rain, splash water and dust.

FR 2 463 566 A discloses a mobile solar power plant built on a pushcart, which can be moved by hand over not too long distances. The Solar panel is mounted on a pole and thus highly susceptible to wind. The electric components are accommodated in a box. There are no provisions described to prohibit heat accumulation within the box. Rechargeable batteries lose their capacity in short term when they get too hot.

DE 4 027 365 A1 discloses a conventional bicycle trailer, in which rechargeable batteries to provide electricity to the pulling bicycle are accommodated. It is proposed to cover the rechargeable batteries by the solar panel. There are no provisions described to prohibit heat accumulation below the covering solar panel in the area of the rechargeable batteries. There are no further electric components described like a charge controller. The disclosed bicycle trailer with a covering solar panel is not suitable for practice, because rechargeable batteries lose their capacity in short term when they get too hot or overcharged, in particular if both conditions are met.

Furthermore there are several mobile solar power plants disclosed, which use a motorized vehicle trailer as the basis of construction and by weight and size are designed to be pulled by a motorized vehicle. In particular such devices are described in U.S. Pat. No. 5,969,591 A, GB 2 339 747 A, WO 02/056440 A2 and WO 2007/039732 A2. Transport over long distances by hand or by bicycle are therefore excluded for most of the disclosed solutions. They are also not designed, to be transported cheaply in container over longer distances, because they do not consist of efficiently stackable parts. Furthermore in the disclosed solutions the problem of heat accumulation below solar panels is not accounted for.

### SUMMARY OF THE INVENTION

The object of the invention is to create a solar generator, in particular a bicycle trailer which can easily be assembled and can be produced and transported cost effectively. The above-described object is solved by a solar generator, in particular a bicycle trailer, having a supporting structure with at least one wheel, a box arranged on the supporting structure, a solar panel attached to the box, and at least one electric module disposed in the box. The solar panel and box are configured so that the electric module is protected from rain from the side by the box and from the top by the solar panel. The solar generator also includes at least one provision to protect against heat accumulation, the at least one provision being arranged and dimensioned to reduce heat accumulation below the solar panel in the box, thereby protecting the at least one electric module against overheating. The solar generator preferably comprises a construction design, which can easily be pulled by hand or by bicycle over longer distances. In this way the solar generator can be brought to the respective place of use according to the local need for electricity. The solar generator is preferably constructed similar to a bicycle trailer and therefore in particular also suited to be pulled by bicycle over longer distances. In lack of a bicycle the solar generator can also be pulled by hand. This is in particular useful in landscapes bad suited for bicycles. The solar generator is preferably constructed with equipment for the easy change of two different drawbars, one with a handle to be pulled by hand, the other one with a coupling to be pulled by bicycle. The solar generator is preferably constructed in a way, that it can be transported partly assembled in a space saving manner, in a way that large quantities of it can be transported efficiently over long distances, for example in containers. The partly assembled parts can come from production sites far apart and be efficiently transported for easy final assemblage in the region of the planned use. Finally assembled in the country of use it can then easily be pulled on its wheels, so that high powered versions are possible as well, which are too heavy to be carried by hand. In a preferred embodiment the solar generator has two wheels which are equipped with pneumatic tires, so that it can be pulled easily also on uneven roads. At least one solar panel is attached to the trailer.

In a further preferred embodiment the solar generator has equipment for storing energy, in particular a rechargeable battery. Below the solar panel and above the trailer axle, for example, the rechargeable battery and beside it the charge controller and the inverter are placed. The center of gravity of the trailer is chosen such that the trailer has two stable positions when put down, either tilted to the back side, with the solar panel in a steep position, or tilted to the front side with the solar panel in a less steep position, so that the solar panel can be oriented in the better of the two possibilities depending on declination and time of the year and the day. A third, steepest, position can be achieved by having the solar panel in an open and inclined position. The direction to the sun is achieved by a short lift of the solar generator and turning it around its own axis. At the drawbar a third, smaller, wheel can be attached, similar to vehicle trailers or caravans, which does not serve for transport but is only be used during stance. In a preferred embodiment the stand wheel is in a fixed position transverse to the moving direction of the trailer and therefore to the solar panel and has a slow driving mechanism with a step motor and a reduction gear, so that the solar generator can track the sun with its own drive.

In another preferred embodiment the solar generator has four wheels, which are equipped with pneumatic tires, so that it can be pulled easily also on uneven roads. At least one solar panel is attached to the solar generator. The backside axle is fixed; the front axle is turnable and attached to a drawbar, similar to a hay wagon. The front axle with the drawbar can in a preferred embodiment be set in a fixed position to the left or right of the solar generator. The drawbar is preferably removable and, for that matter, exchangeable. The wheels of the front axle have a slow driving mechanism with a step motor and a reduction gear, so that the solar generator can track the sun with its own drive.

In a further preferred embodiment on the solar generator with wheels, which are equipped with pneumatic tires, so that it can be pulled easily also on uneven paves, there are mounted several solar panels in a way, that they can be folded together to a transportable state and the solar generator has a width well suited for transport and the solar panels can be unfolded in stationary use for increase of the solar panel area. In a further preferred embodiment the unfolded panels are not active solar panels but reflecting panels, which reflect additional sun rays on the active solar panel. Such solar generators with additional panels can have a tracking mechanism as described above.

In another preferred embodiment one of the above-described solar generators has equipments for stationary use on the ground so that the solar generator can also be used during windy conditions. The wheels are in a preferred embodiment equipped with a locking break, so that the solar generator cannot roll away so easily. In case of the above-described equipments enabling to turn itself after the sun, the locking brake is constructed that it acts on a differential gear on the fixed axle.

In a further preferred embodiment on the solar generator are attached bails for ropes, so that the solar generator can be anchored on the ground similar to a tent with cords and tent pegs. In case of the above described equipments enabling to turn itself after the sun, the bails are placed near the turning center of the fixed axle, so that the automatic tracking is still possible. In a preferred embodiment a single axis solar generator, which in stationary use is tilted either to the front edge or to the back edge, on the edges or on the corners of these edges are anchor equipments attached in such a way, that they anchor themselves into the ground when the solar generator moves, for example because of wind.

In a preferred embodiment the solar panel is integrated into a box, which together cover one or more electric modules, in particular rechargeable battery, charge controller, inverter, and therefore shelter them against weather conditions, in particular rain, splash water and dust, from above (by the solar panel) and sideways (by the box). In a preferred embodiment the integration of the solar panel in the box is done with a sealing, in particular a sealing made of rubber or silicone, to be waterproof, so no rain water can get inside. The box can in a preferred embodiment be made of plastics, in particular of a thermoplast or a duroplast with the respective suitable and known manufacturing procedures.

The unit of the box, in particular of a box made of plastics, and the solar panel is preferably constructed such that they can be stacked within one another and can therefore be transported efficiently in large numbers, for example in containers or on loading platforms of vehicles. Said ability to be stacked within one another is reached in that the walls of the box, in particular a box made of plastics, are conically designed. In a preferred embodiment the distance during the stacking is determined by lugs which stand out on the inner side and so a lateral pressure on the conical walls in the stack are avoided. At the same time the distance is chosen so that on the rear side of the solar panel there is enough space for the connecting box, the connecting cables, connecting plugs and for the isolation.

In a preferred embodiment equipment to protect against overheating of the electrical modules is provided. To protect against heat accumulation under the solar panel an isolation layer is attached directly behind the solar panel. The isolation layer can also be integrated directly in the solar panel. The isolation layer can consist of vacuum, as known from isolating windows and disclosed for example in U.S. Pat. No. 4,683,154 A. In a further preferred embodiment the heat accumulation is avoided by cooling mechanisms. In particular said box, in particular a box made of plastics, is in a preferred embodiment equipped with ventilation equipment, for example ventilation holes, ventilation slots or ventilation gills. The ventilation equipments are constructed in such a way, for example by inclined ventilation gills, so that rain or splash water is drained to the outside. The ventilation equipments contain in a further preferred embodiment air filter to protect against dust. The ventilation equipments are preferably attached to the two small sides on the front side and on the back side to enable an air stream in the inside, in particular using the stack effect when the solar generator is tilted to the front side or to the back side. For a stronger air stream to guard the said electric modules in a further preferred embodiment there is a cooling ventilator installed. Said cooling ventilator can be equipped with a temperature dependent regulation, which switches on when a certain threshold temperature is reached and which increase the air circulation through the ventilation holes. In a further preferred embodiment on the back side of the solar panel a water cooling system is integrated. This can be reached for example with a glass-fiber reinforced plastic (GRP) panel, as disclosed in EP 1 860 706 A1. In a preferred embodiment the electricity using devices are connected via a thermally controlled electric current fuse, so that at higher temperatures the maximal power output is stronger limited. In such way it is reached that on one hand this leads to a lower amount of heat waste produced by the electric modules and on the other hand the electric modules are operating further away of their limit of allowed temperature. Both of these features increase the life expectancy of the electric modules.

In a further preferred embodiment the rechargeable battery is mounted with a plug-in module for rapid exchange. With this a full battery can be taken away and an empty one plugged in for recharging. This enables for example the spatial separation of electricity generation and electricity use. For example a bicycle can be equipped with an electric motor and with a plug in module for a battery as well.

In a further preferred embodiment the electricity of the solar generator can be conducted with a cable to a bicycle equipped with an electric motor, which pulls the solar generator, and with this directly driving the electric bicycle or electric motorbike. In a further preferred embodiment the solar generator is itself equipped with at least one electric motor to facilitate its movement. In a preferred embodiment the motors are integrated in the wheels as hub motors.

In a further preferred embodiment the electric motors can be used as generators to recover energy when braking. The regulation can be done by the electric bicycle or on the solar generator itself by means of a sensor which reacts to pressure and/or tension and which is integrated into the drawbar.

In a further preferred embodiment the solar generator is equipped with an alarm system for example against theft or against storm. The alarm system is for example equipped with a movement sensor which measures shocks and when a threshold is reached generates an alarm, for example by an acoustic sound alarm. The activation/deactivation of the alarm can be performed for example by a key or by entering a code. For theft protection there can be built in a positioning equipment, which regularly measures the position, for example by GPS, and transmits the data, for example by mobile communications, to a server or stores them locally and are read out by mobile communications when needed.

In a further preferred embodiment there can be built in a measuring equipment for electrical states and a display, which for example shows the current charging state of the rechargeable battery, the current power generated by the solar generator and the current power withdrawn from the plugged in electricity consumers. In a preferred embodiment from this data a remaining time is estimated and shown. In a further preferred embodiment the power usage can be added over time and the amount of electricity used can be logged and shown for a usage display or for invoicing means. This can also be logged separately for several sockets, on which different electricity consumers are plugged in. The electrical conditions, in particular the usage data, can also be transmitted wirelessly, in particular in local networks like Bluetooth or in wide area networks like mobile communications. The alarm system or the usage logging, for example, can be upgraded as add on modules. Preferably at least one electric module, more preferred almost all of the electric modules, with the exception of the solar panel and its connecting modules, are attached to the base plate. In a preferred embodiment the unit of the box with the embraced solar panel is attached with one or more hinge-joints, preferably on one side, for example on a long side, on the supporting structure. On the side opposite to the hinge joints there is preferably locking equipment attached, for example bails to attach a U-lock. For easy opening there is preferably a spring arm built in. When the box with the solar panel is by means of the hinge joints open and inclined, there is a steep position given, for example 55 degrees to horizontal, so that this opened position can be used as operating position during morning or evening hours. In a more preferred embodiment the opening position of the box and with it the steepness of the embraced solar panel can be locked in different positions, for example by a rod with holes or by a toothed rack.

The additional wheel, also designated as stand wheel, is preferably regulated by a control unit, which itself is regulatory connected with a sensor unit of the solar plant. Thus in a simple way the above mentioned tracking of the trailer to the sun is enabled. The tracker can also be simply regulated such that the tracking speed approximates the rotational speed of the sun (15 degrees per hour), so that during the day the sunlight is optimally used. Several or all modules can be combined into a single module. In particular, charge controller and inverter are commonly integrated into one device.

Inverters can be constructed technically such that multiple solar generators can be hooked up to increase the power producible together. This is achieved by phase synchronization of the generated alternating currents. The synchronization can take place beforehand by a data line connection or by wireless connection or immediately during AC-connection.

The connectors are preferably constructed in a way, that using them at least one module, preferably the rechargeable battery, can repeatedly and non-destructively be connected and disconnected from at least one other module. Preferably individual modules can simply be added to upgrade the solar generator. For example an additional rechargeable battery is able to double the runtime or an additional solar panel is able to half the recharge time. The reflecting panels are preferably adjustable mirrors, the reflecting surfaces of which are used to feed the solar panel with sunlight.

### BRIEF DESCRIPTION OF THE DRAWINGS

Further advantages, features and details of the invention can be taken from the following description, which in reference to the drawings various embodiments are described in detail.

In the drawings

FIG. 1 is a simplified perspective drawing of the solar generator according to an embodiment of the invention;

FIG. 2 is a schematic exploded drawing of a supporting structure (1) made of partial structures (40,41,42,43,44), two wheels (2) and two alternative drawbars (45) of the solar generator of FIG. 1 in top view;

FIG. 3 is a supporting structure with holders (49,50), a wheel (2), a base plate (13), a wheel house (48) and a drawbar (45) of the solar generator of FIG. 1 in side view;

FIG. 4 is a base plate (13) of the solar generator of FIG. 1 with a wheel house (48) and electric modules (4,5,6,7,8,9,14) and connections in top view;

FIG. 5 is a schematic drawing of a stack of multiple boxes (10) with lugs (53) and embraced solar panels (3) and with an isolation layer (51) behind them of the solar generator of FIG. 1 lying on the back in a cross-sectional view;

FIG. 6 is a schematic drawing of another embodiment of a stack of multiple boxes (10) with lugs (53) and embraced solar panels (3) with double-walled glazing (52) of the solar generator of FIG. 1 lying on the back in a cross-sectional view;

FIG. 7 is a schematic drawing of the solar generator of FIG. 1, yet with a solar panel (3) attached with an inclination and with a drawbar (45) for coupling to a bicycle, in side view in transportation position;

FIG. 8 is the solar generator of FIG. 7 in a first resting position;

FIG. 9 is the solar generator of FIG. 7 in a second resting position;

FIG. 10 is a solar generator like in FIGS. 7 to 9, yet with a horizontally mounted solar panel (3) similar to FIG. 1, according to another embodiment comprising a stand wheel.

### DETAILED DESCRIPTION OF THE PREFERRED EMBODIMENTS

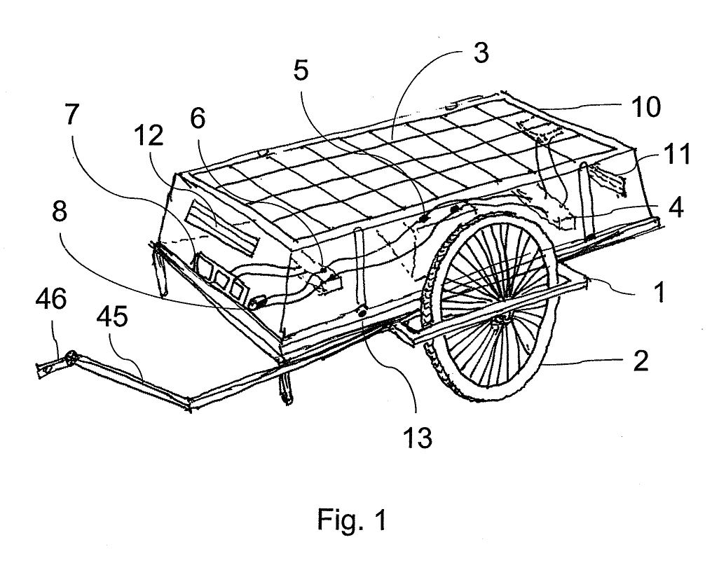

In FIGS. 1 to 10 there are various embodiments of the solar generator according to the invention in different views. In FIG. 1 there is a solar generator constructed as a bicycle trailer in a simplified perspective drawing. The solar generator comprises the supporting structure 1, which is also called the frame of the trailer.

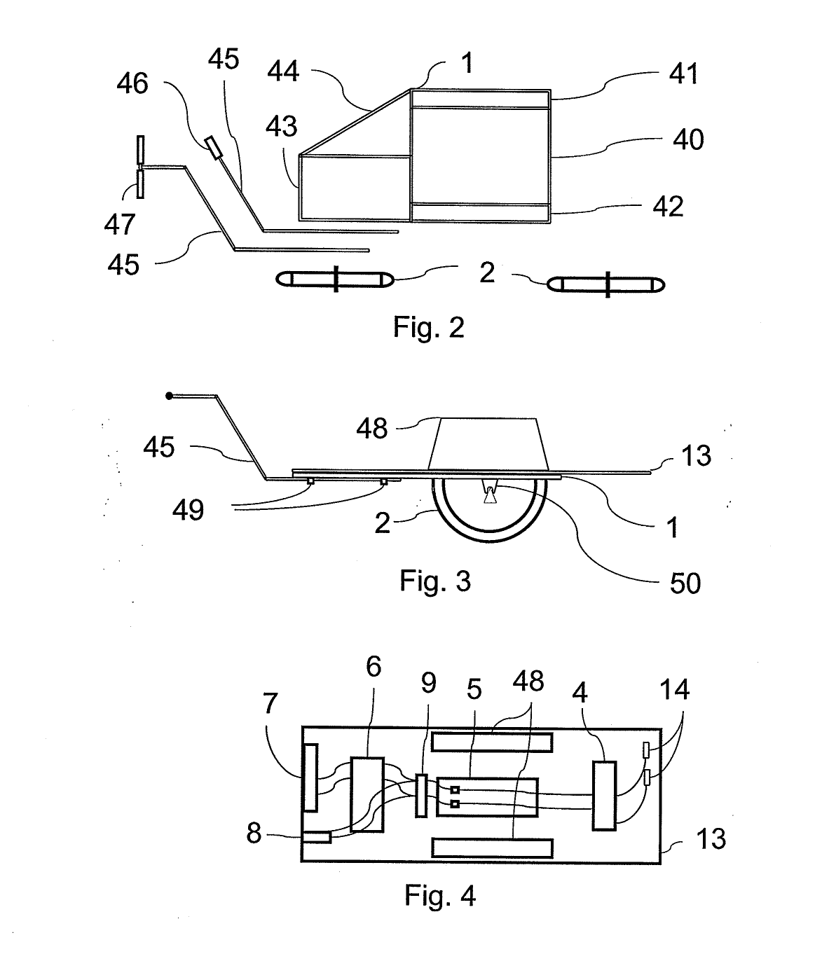

Supporting structure 1 has, as is seen in the top view of FIG. 2, in essence the shape of a rectangle 40, on the long side of which there are two additional rectangles 41,42. To the front side there are another rectangle 43 and a cross stay 44. The frame parts 40 to 44 are for example made of metal section. The rectangles 41,42 serve with holders 50 (see FIG. 3) as mountings and bearings for wheels 2, which are also called carrying wheels. The rectangles 41 and 42 can according to FIG. 2 lie inside rectangle 40, by which the width of the total construction is considerably smaller compared to the construction shown in FIG. 1. Wheels 2 are for example pneumatic tires with a diameter of at least 10 inches, preferably of at least 16 inches, more preferably of at least 20 inches. On rectangle 43 of supporting structure 1 a drawbar 45 is attached.

In FIG. 3 is shown in side view that drawbar 45 is attached with holders 49 on frame 1, thus different drawbars are easily changed.

A coupling 46 of the drawbar 45 serves to couple the trailer in usual ways with a bicycle. The free end of drawbar 45 can further be used as handle 47 to pull the trailer by hand. Drawbar 45 can be designed as low docking drawbar to be coupled near to the rear wheel of the bicycle. Drawbar 45 can also be designed as high docking drawbar to be coupled near the saddle pole of the bicycle. Drawbar 45 is preferably constructed removable and accordingly exchangeable, which is realized by holders 49.

The top side the trailer is covered by solar panel 3, so that nearly the entire trailer's top surface area is exposed to solar radiation. Beneath the solar panel there are arranged charging controller 4, rechargeable battery 5, fuse 9 and inverter 6.

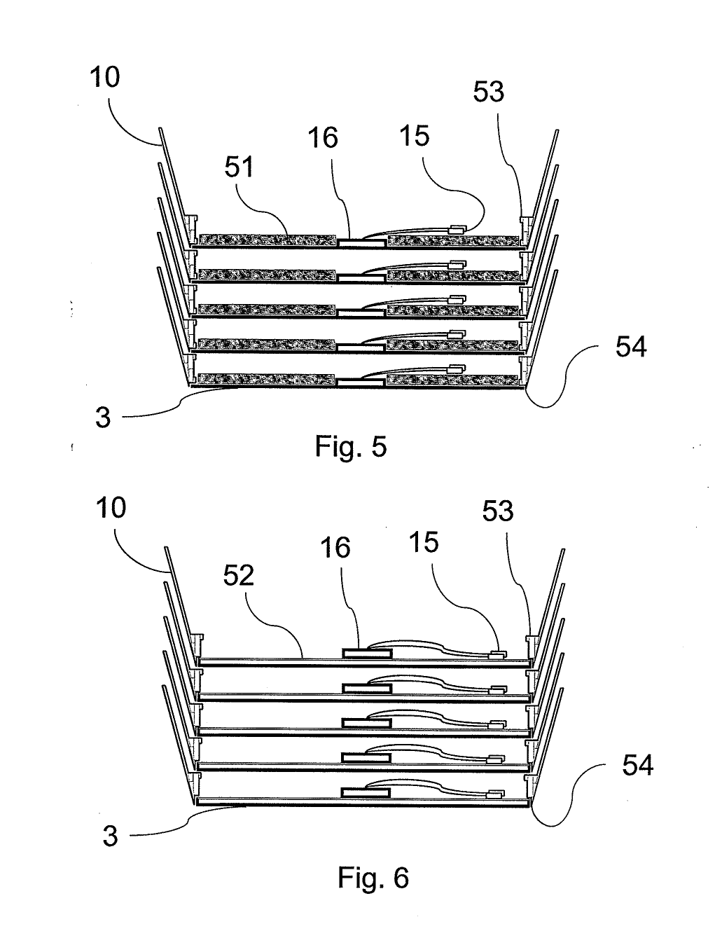

On the front side of the trailer there are connecting modules 7, 8. Connecting module 7 comprises preferably a socket for alternating current. Connecting module 8 comprises preferably a socket for 12V DC, which can be similar to the sockets used in vehicles for cigarette lighters. Connecting modules 7,8 are preferably built in the side of box 10 in such a way, that plugs can be plugged in from outside into sockets of connecting modules 7,8. On the supporting structure 1 or on the base plate 13 is further attached a box 10, which in essence is designed as a cuboid without a bottom, comprising a front outer wall, a rear outer wall and two side walls. To the top box 10 is closed by solar panel 3 and sealed waterproof by sealing 54 (see FIGS. 5 and 6). To the bottom box 10 is open. Box 10 lies in resting position on base plate 13, which closes the inner space on the bottom side. Box 10 is attached with hinge joints on the long side of the base plate and can be opened into an inclined position. The open position is stabilized with a spring arm and is fully functional. The walls of box 10 are cone-shaped (i.e., tapered outward), because of this multiple boxes can be stacked into one another. Lugs 53 on the inside determine the stacking distance. In the rear outer wall ventilation gills 11 are attached. In the front outer wall similarly ventilation gills 12 are attached. Ventilation gills 11, 12 enable a flow through the inner space in longitudinal direction. A tilted position of the solar generator provides a stack-effect. Therefore in a simple way a cooling of the modules arranged in the inside is enabled. An additional ventilator, which is preferably switched on in a temperature dependent manner, can increase the air flow for cooling.

In FIG. 4 it can be seen, that modules 5 and 6, which are indicated in FIG. 1 by broken lines, are attached to base plate 13, which in itself is attached to supporting structure 1 and which closes box 10 on the bottom side. The base plate 13 is preferably detachable, which means repeatedly and non-destructively separable, for example by bolted fastening, attached to supporting structure 1 and/or box 10. In case a narrow design with wheel suspensions inside by means of rectangles 41 and 42 is chosen, base plate 13 has cut-outs, which are under roof of wheel houses 48 to protect the modules from dirt of the wheels. Wheel houses 48 are of metal sheet and help to dissipate heat waste from the interior. In case the base plate 13 is strong enough, supporting structure 1 can be omitted. On the bottom side of base plate 13 are then holders 50 attached for the axles of wheels 2. The individual modules are preferably electrically connected with connectors 14, 15. Connectors 14, 15 (see FIGS. 4 to 6) are preferably constructed such that they enable in an easy way a secure and stable electric connection between the modules. The connection is preferably constructed detachable, which means repeatedly and non-destructively separable. In FIGS. 5 and 6 there are multiple boxes 10, without base plates, stacked together and shown lying on the back side. The base plate 13 (in FIGS. 1, 3 and 4) is preferably constructed as separate component, which is attached, preferably detachable, to box 10 or frame 1, respectively. Shown as stacks in FIGS. 5 and 6 are boxes 10, to each of which there is solar panel 3 attached and sealed using sealing 54. Solar panel 3 comprises a connection module 16, which is also called junction box. From connection module 16 start conduction cables, to the ends of which there are attached connectors 15, which are connectable to connectors 14 (as seen in FIG. 4).

To protect against overheating due to heat accumulation behind the solar panel there is an isolation layer 51 attached directly behind solar panel 3, as seen in the cross section in FIG. 5. In FIG. 6 there is shown a vacuum isolation between double glazings 52, as known from isolating windows.

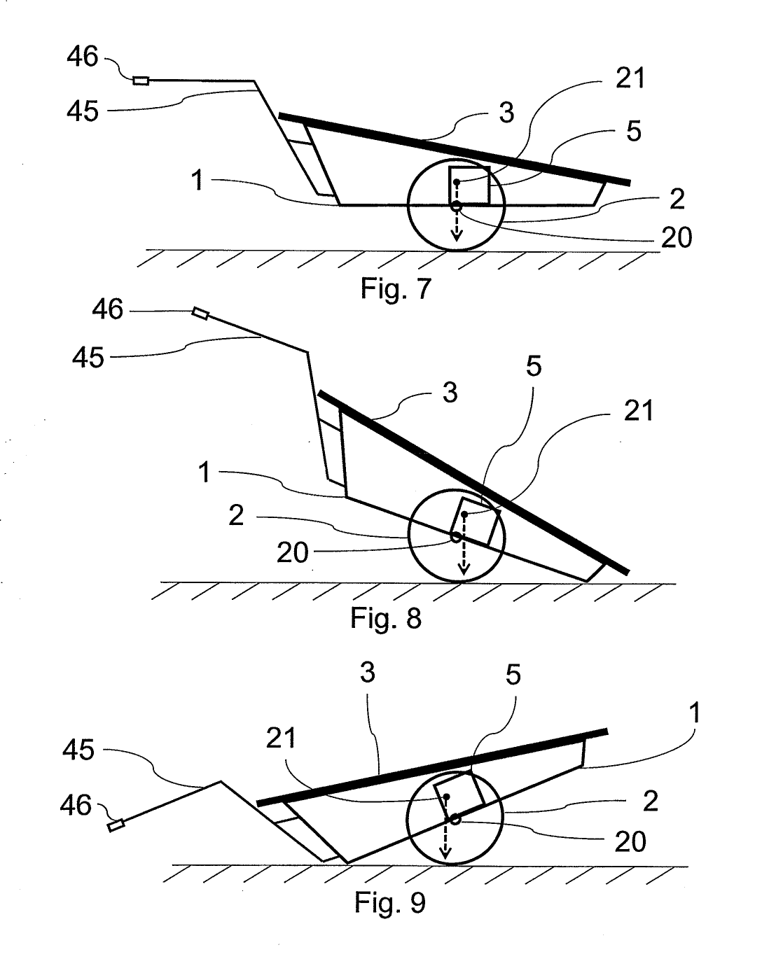

FIGS. 7 to 9 show the solar generator of FIGS. 1 to 6, yet strongly simplified, in various positions. The axle of the solar generator is designated in FIGS. 7 to 9 as 20 and is transversal to the plane of drawing. The center of mass of the solar generator is designated in FIGS. 7 to 9 as 21 and lies in the transport position or traveling position as shown in FIG. 7 approximately vertically above axle 20.

For simplification FIGS. 7 to 9 show the heaviest module only, which is the rechargeable battery 5. The rechargeable battery 5 is, as shown in FIGS. 8 and 9, placed near the axle 20, such that in both of the shown positions of FIGS. 8 and 9, respectively, also called resting positions, a stable stance of the solar generator is insured. The resting positions can also be called operating positions, though the solar generator can as well be operated in transport or traveling position.

In FIG. 8 the solar generator is set tilted to the rear, whereupon center of mass 21 comes to lie behind axle 20. The surface of the solar panel 3 is somewhat steeper inclined compared to the traveling position shown in FIG. 7, which is also called transport position.

In FIG. 9 the solar generator is set tilted to the front, whereupon center of mass 21 comes to lie before axle 20. In this position the surface of the solar panel 3 is in approximately the same angle as in the traveling or transport position, however inclined to the other side. Inclination or tilt of the surface of solar panel 3 is amongst other things dependent on the relation of the frame's length to the axle height of the solar generator.

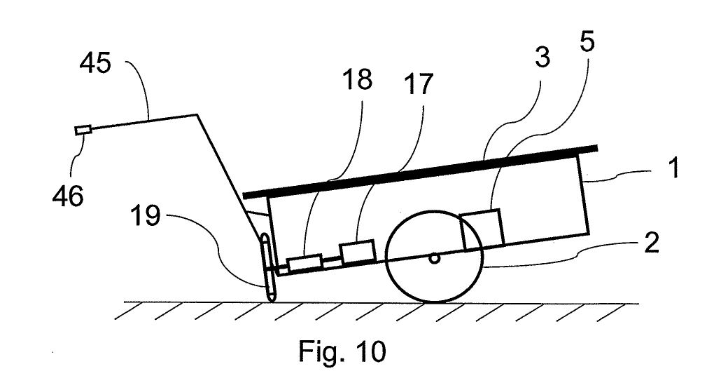

FIG. 10 shows another embodiment of the solar generator, which comprises in addition to the two carrying wheels 2 another wheel 19, also called stand wheel. Wheel 19 is driven by step motor 17 and reduction gear 18 and attached rotating transversal to the longitudinal axis of the solar generator. Stand wheel 19 serves preferably to automatically track the sun with the solar generator.

Technical data of electric components of an embodiment as example:

Solar panel:

Solar-Fabrik SF130: 36 cells polycrystalline, 130 watt peak power, working voltage at maximum power about 16 to 18 volts. Frameless version. Size 1448×663 mm. Thickness 5 mm, including junction box 32 mm. Weight 10.5 kg.

Charge controller:

Steca Solarix. Size 188×106×49 mm. Weight 0.42 kg.

Rechargeable battery:

Deta Solarbatterie 12V, 105 Ah, Size 353×175×190 mm. Weight 24 kg.

Fuse:

Hager MBN563 1+N 63A. Continuous power threshold 800 W at 32° C., 700 W at 42° C. and 600 W at 52° C. Weight 0.3 kg.

Inverter:

Steca AJ1000-12, 12V. Continuous power 800 W, for 30 minutes 1000 W, for 5 seconds 2000 W. Size 455×142×84 mm. Weight 8.5 kg.

The weight of the listed components adds up to 44 kg, in addition are cables and connecting equipment. Including support structure, 20-inch wheels, drawbar, base plate and box made of glass-fiber reinforced plastic (GRP) the total weight in the version with the listed electric components is approximately 75 kg. This version can easily be pulled or pushed by a person, including door sills or a ramp which is not too steep. It can be lifted by two persons and fits, with the drawbar removed, in the extended loading space of a station wagon with flattened rear seats.

1.-20. (canceled)

21. A solar generator, comprising:
a supporting structure with at least one wheel;
a box arranged on said supporting structure;
a solar panel attached to said box;
at least one electric module disposed in said box, said solar panel and said box being arranged and dimensioned so that said electric module is covered for protection against rain from the side by said box and from the top at least by said solar panel; and
at least one heat protection device arranged and dimensioned to reduce heat accumulation below the covering solar panel within said box, thereby protecting the at least one electric module against overheating.

22. The solar generator of claim 21, wherein said solar panel is held by sidewalls of said box, and said solar panel is sealed waterproof to said box.

23. The solar generator of claim 21, wherein said supporting structure comprises a frame to which a base plate, said at least one electric module being mounted on said base plate.

24. The solar generator of claim 21, wherein said at least one heat protection device comprises at least one ventilation gill built into said box to reduce heat accumulation.

25. The solar generator of claim 24, wherein said box is plastic.

26. The solar generator of claim 24, wherein said at least one heat protection device further comprises a ventilator fan built into said box.

27. The solar generator of claim 21, wherein said at least one heat protection device further comprises a ventilator fan built into said box.

28. The solar generator of claim 21, wherein said box is configured such that multiple boxes can be stacked into one another.

29. The solar generator of claim 21, wherein said box together with said solar panel are constructed such that they can be stacked into one another.

30. The solar generator of claim 22, wherein said box and solar panel are configured so that they can be stacked into one another.

31. The solar generator of claim 21, wherein said at least one heat protection device includes an isolation attached to the back side of said solar panel to reduce heat accumulation in the area of said at least one electric module.

32. The solar generator of claim 21, further comprising a rechargeable battery, a charge controller, a connecting module and an inverter.

33. The solar generator of claim 21, further comprising an alarm system.

34. The solar generator of claim 21, further comprising an electricity consumption meter.

35. The solar generator of claim 21, wherein a wall of said box includes a socket to connect an electric cable.

36. A combination of a solar panel and a box for a solar generator having a supporting structure with at least one wheel, said box being designed such that multiple items of the combination of said box and said solar panel can be stacked into one another.
